(19) United States
(12) Patent Application Publication
(10) Pub. No.: US 2020/0303673 A1
(43) Pub. Date: Sep. 24, 2020

(54) DISPLAY PANEL AND DISPLAY DEVICE

(71) Applicant: Shanghai Tianma AM-OLED Co., Ltd., Shanghai (CN)

(72) Inventors: Shuang Cheng, Shanghai (CN); Jinghua Niu, Shanghai (CN); Mingzhi Dai, Shanghai (CN); Yinhe Liu, Shanghai (CN); Jianyun Wang, Shanghai (CN); Yibin Xing, Shanghai (CN)

(73) Assignee: Shanghai Tianma AM-OLED Co., Ltd., Shanghai (CN)

(21) Appl. No.: 16/459,920

(22) Filed: Jul. 2, 2019

(30) Foreign Application Priority Data
Mar. 22, 2019 (CN) 201910222360.9

(51) Int. Cl. H01L 51/52

(52) U.S. Cl. CPC H01L 51/5221; H01L 51/5262; H01L 51/5206

(57) ABSTRACT

Provided are a display panel and a display device. The display panel includes multiple light-emitting devices. Each of the multiple light-emitting devices includes a red light-emitting device, a green light-emitting device and a blue light-emitting device. The red light-emitting device includes a red light-emitting layer, a peak wavelength of a red spectrum emitted by the red light-emitting device is λ₁₁, and a peak wavelength of an intrinsic emission spectrum of a red light-emitting material in the red light-emitting layer is λ₁₂. The green light-emitting device includes a green light-emitting layer, a peak wavelength of a green spectrum emitted by the green light-emitting device is λ₂₁, and a peak wavelength of an intrinsic emission spectrum of a green light-emitting material in the green light-emitting layer is λ₂₂. Δ1=λ₁₁−λ₁₂, Δ2=λ₂₁−λ₂₂.

### CROSS-REFERENCES TO RELATED APPLICATIONS

This application claims priority to Chinese patent application No. 201910222360.9 filed on Mar. 22, 2019, the disclosure of which is incorporated herein by reference in its entirety.

### TECHNICAL FIELD

The present disclosure relates to display techniques and, in particular, to a display panel and a display device including the display panel.

### BACKGROUND

With the continuous development of display techniques, consumers' requirements for display panels have been continuously improved, and various display panels have emerged endlessly and been rapidly developed, such as liquid crystal display panels, organic light-emitting display panels, etc. On this basis, display techniques, such as a 3-dimensional display, a touch display technology, a curved display, an ultra-high resolution display and an anti-peep display, are constantly emerging to meet the demands of consumers.

Organic light-emitting display panels have become the mainstream product of the current display industry due to their advantages such as light weight, high contrast, low energy consumption, and easy implementation of flexibility, and have been widely favored by consumers. However, at present, there are still some problems in the organic light-emitting display panel, which affects its further development. For example, a viewing angle color shift is a problem. The display effect of the organic light-emitting display panel changes as the viewing angle is changed. Color distortion, brightness degradation, greening and other problems are all obvious viewing angle color shift problems in the organic light-emitting display panel. Therefore, how to reduce the difference between the display at a large viewing angle and the display at a positive viewing angle of the organic light-emitting display panel is an urgent problem in the display industry to be solved.

### SUMMARY

In view of the above, the present disclosure provides a display panel and a display device for solving the phenomenon that the color of the organic light-emitting display panel tends to be distorted at a large viewing angle with respect to a positive viewing angle, thereby alleviating the viewing angle color shift problem of the display panel.

An aspect of embodiments of the present disclosure provides a display panel. The display panel includes:

multiple light-emitting devices, where each of the multiple light-emitting devices includes a red light-emitting device, a green light-emitting device and a blue light-emitting device.

The red light-emitting device includes a red light-emitting layer, a peak wavelength of a red spectrum emitted by the red light-emitting device is λ₁₁, and a peak wavelength of an intrinsic emission spectrum of a red light-emitting material in the red light-emitting layer is λ₁₂. The green light-emitting device includes a green light-emitting layer, a peak wavelength of a green spectrum emitted by the green light-emitting device is λ₂₁, and a peak wavelength of an intrinsic emission spectrum of a green light-emitting material in the green light-emitting layer is λ₂₂. The blue light-emitting device includes a blue light-emitting layer, a peak wavelength of a blue spectrum emitted by the blue light-emitting device is λ₃₁, and a peak wavelength of an intrinsic emission spectrum of a blue light-emitting material in the blue light-emitting layer is λ₃₂.

Where, −1 nm≤Δ1=λ₁₁−λ₁₂≤5 nm.

2 nm≤Δ2=λ₂₁−λ₂₂≤7 nm; and

−2 nm≤Δ3=λ₃₁−λ₃₂≤2 nm.

Another aspect of the embodiments of the present disclosure provides a display device including the display panel described above.

From the above description, it is known that in the display panel and the display device provided in the embodiments of the present disclosure, the phenomenon of viewing angle color shift of the display panel at the large viewing angle is corrected by setting a difference between the peak wavelength of the red spectrum of the red light-emitting device and the peak wavelength of the intrinsic emission spectrum of the red light-emitting material to be −1 nm≤λ₁₁−λ₁₂≤5 nm, setting a difference between the peak wavelength of the green spectrum of the green light-emitting device and the peak wavelength of the intrinsic emission spectrum of the green light-emitting material to be 2 nm≤λ₂₁−λ₂₂≤7 nm, and setting a difference between the peak wavelength of the blue spectrum of the blue light-emitting device and the peak wavelength of the intrinsic emission spectrum of the blue light-emitting material to be −2 nm≤λ₃₁−λ₃₂≤2 nm. As shown in research, when the display panel is viewed at the large viewing angle, a blue shift occurs in the wavelengths of the light emitted by the light-emitting devices, that is, the wavelengths shift toward the short-wavelength direction. The change of the wavelength causes the color temperature change of the light, and the effect observed by the human eye is also distorted. Therefore, the present disclosure may offset the blue shift phenomenon to some extent by adjusting the peak wavelengths of the emission spectra of the light-emitting devices with respect to the peak wavelengths of intrinsic emission spectra of the light-emitting materials, thereby ensuring the normal display effect of the display panel at the large viewing angle.

### BRIEF DESCRIPTION OF DRAWINGS

FIG. 1 is a schematic diagram of a light-emitting device according to an embodiment of the present disclosure;

FIG. 2 is a schematic diagram of another light-emitting device according to an embodiment of the present disclosure; and

FIG. 3 is a schematic diagram of a display device according to an embodiment of the present disclosure.

### DETAILED DESCRIPTION

To obtain a clearer understanding of objects, features and advantages of the present disclosure, a description of the present disclosure will be given below in conjunction with the drawings and embodiments.

It is to be noted that details are set forth below to facilitate a thorough understanding of the present disclosure. However, the present disclosure may be implemented by various embodiments different from the embodiments described herein, and those skilled in the art may make similar generalizations without departing from the spirit of the present disclosure. Therefore, the present disclosure is not limited to the specific embodiments disclosed below.

An aspect of the embodiments of the present disclosure provides a display panel. The display panel includes multiple light-emitting devices. The display panel may be an organic light-emitting display panel. Each light-emitting device includes an anode, a cathode and an organic light-emitting layer disposed between the anode and the cathode. A voltage is applied between the anode and the cathode to excite charge carriers to move and act on the organic light-emitting layer so as to emit the light. In other embodiments of the present disclosure, the display panel may further be other display panels, such as a quantum-dot light-emitting panel, a nano wafer light-emitting panel and the like, which will not be repeated in the embodiment.

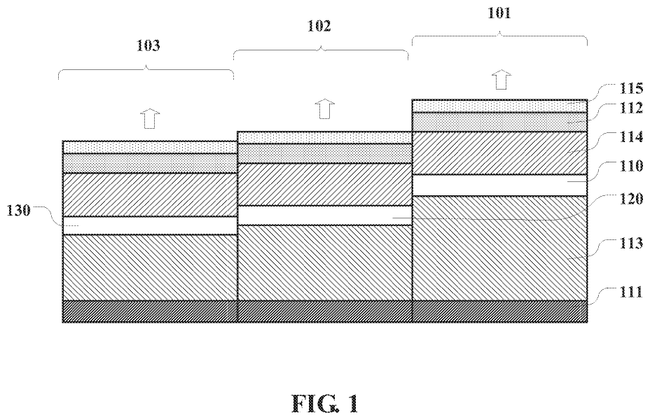

Referring to FIG. 1, FIG. 1 is a schematic diagram of a light-emitting device according to an embodiment of the present disclosure. The light-emitting device includes a red light-emitting device 101, a green light-emitting device 102 and a blue light-emitting device 103. The red light-emitting device 101 includes a red light-emitting layer 110, a peak wavelength of a red spectrum emitted by the red light-emitting device 101 is λ₁₁, and a peak wavelength of an intrinsic emission spectrum of a red light-emitting material in the red light-emitting layer 110 is λ₁₂. The green light-emitting device 102 includes a green light-emitting layer 120, a peak wavelength of a green spectrum emitted by the green light-emitting device 102 is λ₂₁, and a peak wavelength of an intrinsic emission spectrum of a green light-emitting material in the green light-emitting layer 120 is λ₂₂. The blue light-emitting device 103 includes a blue light-emitting layer 130, a peak wavelength of a blue spectrum emitted by the blue light-emitting device 103 is λ₃₁, and a peak wavelength of an intrinsic emission spectrum of a blue light-emitting material in the blue light-emitting layer 130 is λ₃₂. −1 nm≤Δ1=₁₁−λ₁₂≤5 nm, 2 nm≤Δ2=λ₂₁−λ₂₂≤7 nm, and −2 nm≤Δ3=λ₃₁−λ₃₂≤2 nm.

It is to be noted that, besides the light-emitting layer, each light-emitting device in the embodiment further includes an anode 111, a cathode 112, a hole transport layer 113 disposed between the light-emitting layer and the anode 111, an electron transport layer 114 disposed between the light-emitting layer and the cathode 112, and a cap layer 115 disposed on a side of the cathode 112 facing away from the anode 111. A hole generated by the cathode 111 passes through the hole transport layer 113 to arrive at the light-emitting layer. An electron generated by the cathode 112 passes through the electron transport layer 114 to arrive at the light-emitting layer. The electron and the hole combine with each other to form an exciton, and the light-emitting material is excited to emit corresponding light. This process will not be repeated in the embodiment. In addition, directions of arrows in FIG. 1 indicate directions in which each light-emitting layer emits the light.

In addition, in the embodiment, the spectrum emitted by each light-emitting device is a spectrum presented after the light emitted by the light-emitting material passes through the cathode. Because the light passes through the microcavity, part of the light is enhanced, and part of the light is weakened, so that there is a difference between the finally obtained spectrum and the intrinsic emission spectrum of the light-emitting material. The present disclosure is aimed at controlling the difference, thereby reducing the color shift problem of the display panel.

According to existing general observation results, when the display panel is viewed at a large viewing angle, a blue shift occurs in the wavelengths of the light emitted by the light-emitting devices. That is, the wavelengths shift toward the short-wavelength direction. For example, the peak wavelength of the spectrum of the red light-emitting device under the positive viewing angle is 620 nm, but when viewed at a viewing angle of 60°, the peak wavelength of the spectrum may be 612 nm. The change of the wavelength causes the color temperature change of the light, and the effect observed by the human eye is also distorted. Therefore, how to solve the problem of the wavelength blue shift becomes a key technical issue to alleviate the problem of viewing angle color shift. However, for a method of adjusting the structure of the light-emitting device to solve the blue shift problem, the difficulty of the process is increased or the existing process cannot even implement this method. Therefore, inventors of the present application solve this problem in a manner of balancing the spectrum. That is, luminescent spectra of the light-emitting devices with respect to the intrinsic emission spectra of the light-emitting materials are adjusted. By respectively adjusting the spectra of the red light-emitting device 101, the green light-emitting device 102 and the blue light-emitting device 103, a normal display screen may be obtained at the large viewing angle, thereby ensuring the normal display of the display panel at the large viewing angle.

From the above description, it is known that in the display panel provided in the embodiments of the present disclosure, the color shift phenomenon of the display panel at the large viewing angle is corrected by setting a difference between the peak wavelength of the red spectrum of the red light-emitting device 101 and the peak wavelength of the intrinsic emission spectrum of the red light-emitting material to be −1 nm≤λ₁₁−λ₁₂≤5 nm, setting a difference between the peak wavelength of the green spectrum of the green light-emitting device 102 and the peak wavelength of the intrinsic emission spectrum of the green light-emitting material to be 2 nm≤λ₂₁−λ₂₂≤7 nm, and setting a difference between the peak wavelength of the blue spectrum of the blue light-emitting device 103 and the peak wavelength of the intrinsic emission spectrum of the blue light-emitting material to be −2 nm≤λ₃₁−λ₃₂≤2 nm. The present disclosure is aimed at adjusting the peak wavelengths of the emission spectra of the light-emitting devices with respect to the peak wavelengths of intrinsic emission spectra of the light-emitting materials, thereby offsetting the blue shift phenomenon to some extent and ensuring the normal display effect of the display panel at the large viewing angle.

Optionally, in an embodiment, 3 nm≤Δ1+Δ2≤12 nm. That is, a range of the sum of the difference between the peak wavelength of the red spectrum of the red light-emitting device 101 and the peak wavelength of the intrinsic emission spectrum of the red light-emitting material in the red light-emitting layer 110 and the difference between the peak wavelength of the green spectrum of the green light-emitting device 102 and the peak wavelength of the intrinsic emission spectrum of the green light-emitting material in the green light-emitting layer 120 is 3 nm to 12 nm. Based on the above conditions, the inventors of the present application have found that the light color distortion phenomenon of the display panel at the large viewing angle may be eliminated, thereby ensuring the normal display of the display panel at the large viewing angle.

In addition, optionally, in another embodiment, Δ1>0. That is, the difference between the peak wavelength of the red spectrum of the red light-emitting device 101 and the peak wavelength of the intrinsic emission spectrum of the red light-emitting material in the red light-emitting layer 110 is greater than 0. When viewed at the large viewing angle, the spectrum of the each light-emitting device usually moves towards the short wavelength. Therefore, in order to balance this moving trend, the present application sets the peak wavelength of the red light-emitting device to be larger than the peak wavelength of the intrinsic emission spectrum of the red light-emitting material to make the peak of the red light-emitting device move towards the long wavelength by adjusting the microcavity at the initial time, thereby balancing the blue shift at the large viewing angle, and ensuring the normal color without distortion at the large viewing angle.

In addition, similarly, in another embodiment, Δ2>0. That is, the difference between the peak wavelength of the green spectrum emitted by the green light-emitting device 102 and the peak wavelength of the intrinsic emission spectrum of the green light-emitting material in the green light-emitting layer 120 is greater than 0. As mentioned above, the peak wavelength of the green light-emitting device is configured to be larger than the peak wavelength of the intrinsic emission spectrum of the green light-emitting material to make the peak of the green light-emitting device move towards the long wavelength, thereby balancing the blue shift at the large viewing angle, and ensuring the normal color without distortion at the large viewing angle.

Similarly, in another embodiment, Δ3≥0. That is, the difference between the peak wavelength of the blue spectrum emitted by the blue light-emitting device 103 and the peak wavelength of the intrinsic emission spectrum of the blue light-emitting material in the blue light-emitting layer 130 is greater than or equal to 0. According to researches, in the display panel, the blue shift phenomenon in the light of the blue light-emitting device at the large viewing angle is less than that in the light of the green light-emitting device, and is much less than that in the light of the red light-emitting device. Therefore, for the blue light-emitting device, the difference between the peak wavelength of the blue spectrum and the peak wavelength of the intrinsic emission spectrum of the blue light-emitting material in the blue light-emitting layer 130 may be set to be greater than 0, or may be set to be equal to 0, thereby ensuring the normal display of the display screen at the large viewing angle.

Research shows that in the display panel, degrees of blue shift in different colors of light-emitting devices at the large viewing angle are different. The blue shift is the most prominent in the red light followed by the green light, and it is the least prominent in the blue light. Therefore, in an embodiment, optionally, Δ1≥Δ2>Δ3 is set. That is, the differences between the peak wavelengths of the emission spectra of the light-emitting devices and the peak wavelengths of intrinsic emission spectra of the light-emitting materials decrease sequentially in the order of red, green and blue, thereby performing adjustment according to degrees of blue shifts in different kind of light and ensuring the normal display screen of the display panel at the large viewing angle.

In another embodiment, optionally, Δ3=0. Since the blue shift in the blue light at the large viewing angle is the smallest as mentioned above, it may be ensured that the peak wavelength of the blue spectrum emitted by the blue light-emitting device 103 is equal to the peak wavelength of the intrinsic emission spectrum of the blue light-emitting material in the blue light-emitting layer 130, thereby simplifying the process.

In addition, in another embodiment, as shown in FIG. 1, each light-emitting device includes an anode 111 and a cathode 112, a light-emitting layer is disposed between the anode 111 and the cathode 112, the anode 111 is a total reflective anode, the cathode 112 is a semi-transmissive cathode, and a microcavity is formed between the anode 111 and the cathode 112. Since the anode 111 is the total reflective anode and the cathode 112 is the semi-transmissive cathode, part of light emitted by the light-emitting layer is emitted towards the cathode, and part of light is emitted towards the anode. The light is reflected by the total reflective anode and emitted towards the cathode, part of the light emitted towards the cathode is directly emitted from the semi-transmissive cathode, and part of the light is reflected back into the interior of the light-emitting devices and is emitted from the cathode after reflected by the anode. The above process repeats, part of light is enhanced and part of light is offset after interfering the emission of the light having the optical path difference, thereby finally changing the spectrum of the original light emitted by the light-emitting material. This process is called the microcavity effect.

In the embodiment, optionally, the microcavity of the red light-emitting device 101 has a first cavity length D1, the microcavity of the green light-emitting device 102 has a second cavity length D2, and the microcavity of the blue light-emitting device 103 has a third cavity length D3. At least one of following three conditions is met: D1>λ₁₂/2, D2>λ₂₂/2, and D3>λ₃₂/2. According to a calculation formula of the light phase difference is α=2π·ΔL/λ, where α is the phase difference between two correlated beams of light, ΔL is the optical path difference of the two correlated beams of light, and λ is the wavelength, the enhancement of the two correlated beams of light is required to meet a condition, which is α is n·2π, where n is a positive integer and n≥1. Therefore, when the two correlated beams of light are enhanced, the optical path difference ΔL is equal to nλ. Two beams of light that interfere with each other in the microcavity are the light which first passes through the cathode and the light which is first reflected by the cathode and passes through the cathode at the mth time, where m is a positive integer and m≥2. The optical path difference of these beams of light is ΔL=2(m−1)·D, where D is the cavity length of the microcavity. Therefore, an enhancement condition of the two beams of light is 2(m−1)·D=nλ. Generally, in order to reduce the thickness of the display panel, n=1 is selected herein, and since the light intensities of the light first emitted from the cathode and the light second emitted from the cathode are the strongest, m=2 is selected herein, thereby obtaining D=λ/2, which is a condition for the constructive interfere of the microcavity having the cavity length of D with the light having the wavelength of λ. Therefore, when the cavity length D of the microcavity is changed, the wavelength of the light on which the constructive interference is performed is also changed.

In an embodiment, since it is necessary to adjust the peak wavelengths of the emission spectra of the light-emitting devices, according to the above description, the peak wavelengths of the emission spectra of the light-emitting devices are adjusted by adjusting the cavity length of the microcavity. When at least one of three conditions which are D1>λ₁₂/2, D2>λ₂₂/2, and D3>λ₃₂/2 is met, for the light-emitting device having the blue shift at the large viewing angle, the peak wavelength of the emission spectrum of the light-emitting device first moves towards the long wavelength, thereby balancing the blue shift phenomenon and avoiding the phenomenon of viewing angle color shift.

In addition, in response to the forgoing, D1>λ₁₂/2, D2>λ₂₂/2, and D3≥λ₃₂/2. When Δ1>0, Δ2>0 and Δ3≥0, the change of this wavelength may be implemented through the above settings, thereby finally offsetting the blue shift phenomenon.

In another embodiment, optionally, the specific value of D1, D2 and D3 may meet: 240 nm≤D1≤290 nm, 200 nm≤D2≤230 nm, and 160 nm≤D3≤190 nm. The inventors of the present application have found through researches that when D1, D2 and D3 respectively meet this condition, it is possible to implement −1 nm≤Δ1≤5 nm; and 2 nm≤Δ2≤7 nm and −2 nm≤Δ3=λ31−λ32≤2 nm. Thereby, the display panel may also have a normal display effect at the large viewing angle and implement a better white balance.

In addition, in another embodiment, optionally, as shown in FIG. 1, each light-emitting device further includes a cap layer 115. The cap layer 115 is disposed on a side of the cathode 112 of each light-emitting device facing away from the anode 111. A refractive index of the cap layer 115 to light having a wavelength ranging from 380 nm to 720 nm is greater than a refractive index of the cathode 112. On one aspect, as described above, the viewing angle color shift is caused by the blue shift of the light at the large viewing angle. On another aspect, the light in the light-emitting devices is eventually emitted into the air and then enters the observers' eyes. That is, the light comes into an optically thinner medium from an optically dense medium. Therefore, when viewed at the large viewing angle, part of the light may not enter the human eye due to total reflection, resulting in low light output efficiency at the large viewing angle, thereby causing the distortion of the display screen at the large viewing angle. Therefore, in the embodiment, a refractive index of the cap layer 115 to visible light is set to be greater than the refractive index of the cathode 111, so that when emitted from the cathode 111 to the cap layer 115, the light more tends to be emitted along the direction of the positive viewing angle. More light enters the observers' eyes when they observe at the large viewing angle, thereby improving the light output efficiency of the display panel at the large viewing angle and weakening the phenomenon of the viewing angle color shift.

Furthermore, in another embodiment, a refractive index of the cap layer 115 to light having a wavelength ranging from 600 nm to 720 nm is greater than a refractive index of the cap layer 115 to light having a wavelength ranging from 500 nm to 580 nm, and/or a refractive index of the cap layer 115 to light having a wavelength ranging from 400 nm to 490 nm is greater than the refractive index of the cap layer 115 to light having a wavelength ranging from 500 nm to 580 nm. The current researches show that the light output efficiency of the red light decreases fastest at the large viewing angle, followed by the blue light and the green light. Since contrast visual sensitivities of different colors are different in the human eye, the contrast visual sensitivity of the green light is the highest, followed by the blue light and the contrast visual sensitivity of the red light is the lowest. Therefore, at the large viewing angle, as the light output efficiency of the display panel decreases, the light emitting efficiency of the red light decreases most, followed by the blue light and the green light. Therefore, in the embodiment, this difference may be compensated by setting different reflective indexes of the cap layer 115 to light with different wavelength ranges, so that the display panel may easily implement the white balance at the large viewing angle.

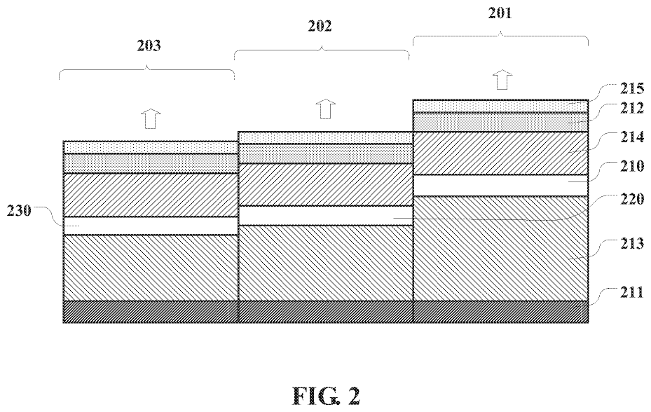

Another aspect of the embodiments of the present disclosure provides another display panel. The display panel includes multiple light-emitting devices. Referring to FIG. 2, FIG. 2 is a schematic diagram of another light-emitting device according to an embodiment of the present disclosure. The multiple light-emitting devices include a red light-emitting device 201, a green light-emitting device 202 and a blue light-emitting device 203. The red light-emitting device 201 includes a red light-emitting layer 210, a peak wavelength of a red spectrum emitted by the red light-emitting device 201 is λ₁₁, and a peak wavelength of an intrinsic emission spectrum of a red light-emitting material in the red light-emitting layer 210 is λ₁₂. The green light-emitting device 202 includes a green light-emitting layer 220, a peak wavelength of a green spectrum emitted by the green light-emitting device 220 is λ₂₁, and a peak wavelength of an intrinsic emission spectrum of a green light-emitting material in the green light-emitting layer 220 is λ₂₂. The blue light-emitting device 203 includes a blue light-emitting layer 230, a peak wavelength of a blue spectrum emitted by the blue light-emitting device 230 is λ₃₁, and a peak wavelength of an intrinsic emission spectrum of a blue light-emitting material in the blue light-emitting layer 230 is λ₃₂. At least one of three conditions is met: Δ1=λ₁₁−λ₁₂, and Δ1>0; Δ2=λ₂₁−λ₂₂, and Δ2>0; and Δ3=λ₃₁−λ₃₂, and Δ3>0.

In an embodiment, as mentioned above, since a blue shift occurs in the wavelengths of the light emitted by the light-emitting devices at the large viewing angle, the light of the light-emitting devices with respect to the peak wavelengths of intrinsic emission spectra of the light-emitting materials moves towards the direction of long wavelength through the microcavity effect at the initial time, thereby offsetting the blue shift phenomenon at the large viewing angle and ensuring the normal display of the display screen at the large viewing angle. The light-emitting devices where the blue shift occurs at the large viewing angle may be adjusted in a targeted manner by meeting at least one of the above three conditions. For example, when the blue shift occurs in the red light-emitting device 201, Δ1=λ₁₁−λ₁₂ and Δ1>0 are set to adjust the blue shift. In condition that the blue shift occurs in both the red light-emitting device 201 and the green light-emitting device 202, Δ1=λ₁₁−λ₁₂ and Δ1>0, and Δ2=λ₂₁−λ₂₂ and Δ2>0 are set to adjust the blue shift in the two light-emitting device.

Optionally, in another embodiment, Δ1>0, Δ2>0 and Δ3≥0. That is, the red light-emitting device, the green light-emitting device and the blue light-emitting device are adjusted correspondingly, thereby avoiding the blue shift phenomenon at the large viewing angle.

Optionally, in another embodiment, as shown in FIG. 2, each light-emitting device includes an anode 211 and a cathode 212, a light-emitting layer is disposed between the anode 211 and the cathode 212, the anode 211 is a total reflective anode, the cathode 212 is a semi-transmissive cathode, and a microcavity is formed between the anode 211 and the cathode 212. Since the anode 211 is the total reflective anode and the cathode 212 is the semi-transmissive cathode, part of light emitted by the light-emitting layer is emitted towards the cathode, and part of light is emitted towards the anode. The light is reflected by the total reflective anode and emitted towards the cathode, part of the light emitted towards the cathode is directly emitted from the semi-transmissive cathode, and part of the light is reflected back into the interior of the light-emitting device and is emitted from the cathode after reflected by the anode. The above process repeats, part of light is enhanced and part of light is offset after interfering the emission of the light having the optical path difference, thereby finally changing the spectrum of the original light emitted by the light-emitting material and causing a microcavity effect.

In an embodiment, optionally, the microcavity of the red light-emitting device 201 has a first cavity length D1, the microcavity of the green light-emitting device 202 has a second cavity length D2, and the microcavity of the blue light-emitting device 203 has a third cavity length D3. At least one of following three conditions is met: D1>λ₁₂/2, D2>λ₂₂/2, and D3>λ₃₂/2. In the microcavity effect, the wavelength of the light of the consecutive interference is proportional to the cavity length D of the microcavity, and in general, D=λ/2 is set to make the light having the wavelength of λ obtain the constructive interference. In the embodiment, the light of the light-emitting devices with respect to the peak wavelengths of intrinsic emission spectra of the light-emitting materials moves towards the direction of long wavelength through the microcavity effect at the initial time. At least one of conditions is met by adjusting the cavity length of the microcavity, thereby adjusting the light-devices where the blue shift occurs in the targeted manner. For example, D1>λ₁₂/2 is set so that Δ1>0, D2>λ₂₂/2 is set so that Δ2>0, and D3>λ₃₂/2 is set so that Δ3>0, thereby adjusting the blue shift phenomenon in the red, green, and blue light-emitting devices. Specially, in the embodiment, D1>λ₁₂/2, D2>λ₂₂/2 and D3>λ₃₂/2. Since the blue shift is less likely to be occurred in the blue light-emitting device, D3 may be equal to λ₃₂/2, thereby simplifying the process.

In addition, in another embodiment, optionally, as shown in FIG. 2, each light-emitting device further includes a cap layer 215. The cap layer 215 is disposed on a side, facing away from the anode 212, of the cathode 211 of each light-emitting device. A refractive index of the cap layer 215 to light having a wavelength ranging from 380 nm to 720 nm is greater than a refractive index of the cathode 212. On one aspect, as described above, the viewing angle color shift is caused by the blue shift of the light at the large viewing angle. On another aspect, the light in the light-emitting devices is eventually emitted into the air and then enters the observers' eyes. That is, the light comes into an optically thinner medium from an optically dense medium. Therefore, when viewed at the large viewing angle, part of the light may not enter the human eye due to total reflection, resulting in low light output efficiency at the large viewing angle, thereby causing the distortion of the display screen at the large viewing angle. Therefore, in the embodiment, a refractive index of the cap layer 215 to visible light is set to be greater than the refractive index of the cathode 211, so that when emitted from the cathode 211 to the cap layer 215, the light more tends to be emitted along the direction of the positive viewing angle. More light enters the observers' eyes when they observe at the large viewing angle, thereby improving the light output efficiency of the display panel at the large viewing angle and weakening the phenomenon of the viewing angle color shift.

Another aspect of the embodiments of the present disclosure further provides a display device including the display panel in any one of embodiments described above.

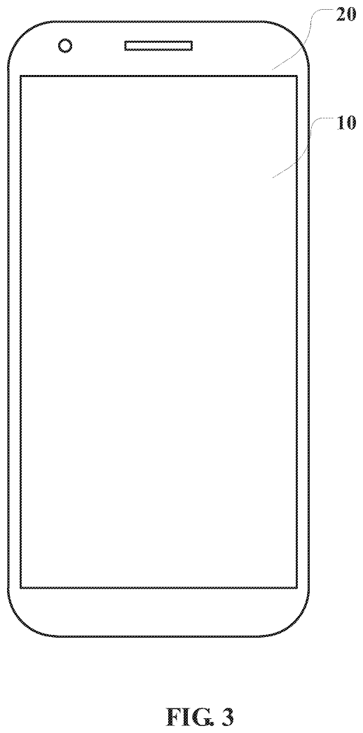

Referring to FIG. 3, FIG. 3 is a schematic diagram of a display device according to an embodiment of the present disclosure. The display device 20 includes a display panel 10. The display panel 10 is the display panel described in any one of embodiments described above. The display device 20 may be a mobile phone, a foldable display screen, a laptop, a television, a watch, an intelligent wearing device, etc., which is not limited in the embodiment.

From the above description, it is known that in the display panel and the display device provided in the embodiments of the present disclosure, the phenomenon of viewing angle color shift of the display panel at the large viewing angle is corrected by setting a difference between the peak wavelength of the red spectrum of the red light-emitting device and the peak wavelength of the intrinsic emission spectrum of the red light-emitting material, setting a difference between the peak wavelength of the green spectrum of the green light-emitting device and the peak wavelength of the intrinsic emission spectrum of the green light-emitting material, and setting a difference between the peak wavelength of the blue spectrum of the blue light-emitting device and the peak wavelength of the intrinsic emission spectrum of the blue light-emitting material. The peak wavelengths of the emission spectra of the light-emitting devices with respect to the peak wavelengths of intrinsic emission spectra of the light-emitting materials are adjusted, thereby offsetting the blue shift phenomenon to some extent and ensuring the normal display effect of the display panel at the large viewing angle.

The above content is a further detailed description of the present disclosure in conjunction with the specific preferred embodiments, and the specific implementation of the present disclosure is not limited to the description. For those skilled in the art to which the present disclosure pertains, a number of simple deductions or substitutions may be made without departing from the concept of the present disclosure and should fall within the protection scope of the present disclosure.

What is claimed is:

1. A display panel, comprising:
a plurality of light-emitting devices, wherein each of the plurality of the light-emitting devices comprises a red light-emitting device, a green light-emitting device and a blue light-emitting device; and
wherein the red light-emitting device comprises a red light-emitting layer, a peak wavelength of a red spectrum emitted by the red light-emitting device is λ₁₁, and a peak wavelength of an intrinsic emission spectrum of a red light-emitting material in the red light-emitting layer is λ₁₂; the green light-emitting device comprises a green light-emitting layer, a peak wavelength of a green spectrum emitted by the green light-emitting device is λ₂₁, and a peak wavelength of an intrinsic emission spectrum of a green light-emitting material in the green light-emitting layer is λ₂₂; and the blue light-emitting device comprises a blue light-emitting layer, a peak wavelength of a blue spectrum emitted by the blue light-emitting device is λ₃₁, and a peak wavelength of an intrinsic emission spectrum of a blue light-emitting material in the blue light-emitting layer is λ₃₂;
wherein, −1 nm≤Δ1=λ₁₁−λ₁₂≤5 nm;
2 nm≤Δ2=λ₂₁−λ₂₂≤7 nm; and
−2 nm≤Δ3=λ₃₁−λ₃₂₂ nm.

2. The display panel of claim 1, wherein
3 nm≤Δ1+Δ2≤12 nm.

3. The display panel of claim 1, wherein
Δ1>0, Δ2>0, and Δ3≥0.

4. The display panel of claim 1, wherein
Δ1≥Δ2>Δ3.

5. The display panel of claim 1, wherein
Δ3=0.

6. The display panel of claim 1, wherein the each of the plurality of the light-emitting devices comprises an anode and a cathode, the red light-emitting layer, the green light-emitting layer and the blue light-emitting layer are disposed between the anode and the cathode, the anode is a total reflective anode, the cathode is a semi-transmissive cathode, and a microcavity is formed between the anode and the cathode.

7. The display panel of claim 6, wherein a microcavity of the red light-emitting device has a first cavity length D1, a microcavity of the green light-emitting device has a second cavity length D2, and a microcavity of the blue light-emitting device has a third cavity length D3, wherein
at least one of following three conditions is met:
D1>λ₁₂/2,
D2>λ₂₂/2; and
D3>λ₃₂/2.

8. The display panel of claim 7, wherein
D1>λ₁₂/2, D2>2λ₂/2 and D3≥λ₃₂/2.

9. The display panel of claim 7, wherein D1, D2 and D3 meet:
240 nm≤D1≤290 nm;
200 nm≤D2≤230 nm; and
160 nm≤D3≤190 nm.

10. The display panel of claim 6, wherein the each of the plurality of the light-emitting devices further comprises a cap layer, the cap layer is disposed on a side of the cathode of the light-emitting device facing away from the anode, and a refractive index of the cap layer to light having a wavelength ranging from 380 nm to 720 nm is greater than a refractive index of the cathode.

11. The display panel of claim 10, wherein a refractive index of the cap layer to light having a wavelength ranging from 600 nm to 720 nm is greater than a refractive index of the cap layer to light having a wavelength ranging from 500 nm to 580 nm, and/or
a refractive index of the cap layer to light having a wavelength ranging from 400 nm to 490 nm is greater than the refractive index of the cap layer to light having a wavelength ranging from 500 nm to 580 nm.

12. A display panel, comprising:
a plurality of light-emitting devices, wherein each of the plurality of the light-emitting devices comprises a red light-emitting device, a green light-emitting device and a blue light-emitting device; and
wherein the red light-emitting device comprises a red light-emitting layer, a peak wavelength of a red spectrum emitted by the red light-emitting device is λ₁₁, and a peak wavelength of an intrinsic emission spectrum of a red light-emitting material in the red light-emitting layer is λ₁₂;
the green light-emitting device comprises a green light-emitting layer, a peak wavelength of a green spectrum emitted by the green light-emitting device is λ₂₁, and a peak wavelength of an intrinsic emission spectrum of a green light-emitting material in the green light-emitting layer is λ₂₂; and the blue light-emitting device comprises a blue light-emitting layer, a peak wavelength of a blue spectrum emitted by the blue light-emitting device is λ₃₁, and a peak wavelength of an intrinsic emission spectrum of a blue light-emitting material in the blue light-emitting layer is λ₃₂;
wherein at least one of following three conditions is met:
Δ1=λ₁₁−λ₁₂, and Δ1>0;
Δ2=λ₂₁−λ₂₂, and Δ2>0; and
Δ3=λ₃₁−λ₃₂, and Δ3>0.

13. The display panel of claim 12, wherein
Δ1>0, Δ2>0, and Δ3≥0.

14. The display panel of claim 12, wherein the each of the plurality of the light-emitting devices comprises an anode and a cathode, the red light-emitting layer, the green light-emitting layer and the blue light-emitting layer are disposed between the anode and the cathode, the anode is a total reflective anode, the cathode is a semi-transmissive cathode, and a microcavity is formed between the anode and the cathode.

15. The display panel of claim 14, wherein a microcavity of the red light-emitting device has a first cavity length D1, a microcavity of the green light-emitting device has a second cavity length D2, a the microcavity of the blue light-emitting device has a third cavity length D3, wherein at least one of following three conditions is met:
D1>λ₁₂/2;
D2>λ₂₂/2; and
D3>λ₃₂/2.

16. The display panel of claim 15, wherein
D1>λ₁₂/2, D2>λ₂₂/2 and D3≥λ₃₂/2.

17. The display panel of claim 14, wherein the each of the plurality of the light-emitting devices further comprises a cap layer, the cap layer is disposed on a side of the cathode of the light-emitting device facing away from the anode, and a refractive index of the cap layer to light having a wavelength ranging from 380 nm to 720 nm is greater than a refractive index of the cathode.

18. A display device, comprising a display panel, wherein the display panel comprises:
a plurality of light-emitting devices, wherein each of the plurality of the light-emitting devices comprises a red light-emitting device, a green light-emitting device and a blue light-emitting device; and
wherein the red light-emitting device comprises a red light-emitting layer, a peak wavelength of a red spectrum emitted by the red light-emitting device is λ₁₁, and a peak wavelength of an intrinsic emission spectrum of a red light-emitting material in the red light-emitting layer is λ₁₂; the green light-emitting device comprises a green light-emitting layer, a peak wavelength of a green spectrum emitted by the green light-emitting device is λ₂₁, and a peak wavelength of an intrinsic emission spectrum of a green light-emitting material in the green light-emitting layer is λ₂₂; and the blue light-emitting device comprises a blue light-emitting layer, a peak wavelength of a blue spectrum emitted by the blue light-emitting device is λ₃₁, and a peak wavelength of an intrinsic emission spectrum of a blue light-emitting material in the blue light-emitting layer is λ₃₂;
wherein, −1 nm≤Δ1=λ₁₁−λ₁₂≤5 nm;
2 nm≤Δ2=λ₂₁−λ₂₂≤7 nm; and
−2 nm≤Δ3=λ₃₁−λ₃₂≤2 nm.

19. A display device, comprising the display panel of claim 12.
